(19) United States
(12) Patent Application Publication
(10) Pub. No.: US 2010/0172072 A1
(43) Pub. Date: Jul. 8, 2010

(54) MULTIPLE ARM ARTICULATING MOUNTING SYSTEM

(75) Inventor: Garry Monaco, Hoffman Estates, IL (US)

Correspondence Address: FOLEY & LARDNER LLP, 321 NORTH CLARK STREET, SUITE 2800, CHICAGO, IL, 60654-5313, US

(73) Assignee: Peerless Industries, Inc.

(21) Appl. No.: 12/636,238

(22) Filed: Dec. 11, 2009

Related U.S. Application Data
(60) Provisional application No. 61/142,555, filed on Jan. 5, 2009.

(51) Int. Cl. H05K 7/00; F16M 13/02

(52) U.S. Cl. 361/679.01; 248/282.1

(57) ABSTRACT

A low profile moveable mounting system for mounting a device to a surface. According to various embodiments, a first pair of rotating arms is rotatably connected to a surface plate attachable to a surface, and a second pair of arms are rotatably connected to the first pair of arms and to a device bracket. The moveable mounting system is selectively moveable between an extended orientation, where the device bracket is horizontally displaced from the surface and a retracted orientation, where the device bracket is positionable within close proximity of the surface. The moveable mounting system may be particularly adapted for mounting a flat panel display device.

### CROSS-REFERENCE TO RELATED PATENT APPLICATIONS

This application claims priority from U.S. Provisional Application No. 61/142,555 filed Jan. 5, 2009 and the contents of which are incorporated herein by reference in their entirety.

### FIELD OF THE INVENTION

The present invention relates generally to mounting systems. More particularly, the present invention relates to moveable mounting systems with articulating arms for use with flat panel televisions, where the position of the television can be adjusted after installation.

### BACKGROUND OF THE INVENTION

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

In recent years, flat panel televisions have become enormously popular in both commercial and residential sectors. As the prices for plasma and liquid crystal display (LCD) flat panel displays have continued to fall, and the quality for the same devices have improved, more and more businesses and individuals have purchased such devices for both home and business entertainment purposes.

One of the advantages of flat panel television units that customers have found particular appealing is their relatively low thickness. Because conventional “tube” televisions have a relatively large depth, the display options for such devices are quite limited. In the residential setting, most users require a television stand or large entertainment center to store the television. Such stands or entertainment centers can take up significant floor space, which is often undesirable. In the commercial or educational setting, users will often install large overhead mounting systems that can contain the television. However these systems usually require professional installation and, once the television is secured to the mount, it is often difficult to access and adjust due to its height. With flat panel televisions, on the other hand, users are presented with a relatively new option: mounting the television directly to the wall. By mounting the television to the wall, a person can eliminate the need to take up potentially valuable floor space.

Although the introduction of flat panel televisions on a wide scale has presented new opportunities to both residential and commercial customers, it has also presented new challenges. In particular, flat panel televisions, while usually having significantly smaller depth or profile than conventional “tube” televisions, tend to be quite heavy. Particularly for flat panel televisions with large screens, this weight can become prohibitively great. With such large weights involved, it is especially important that users can easily, safely, and securely mount the devices. Furthermore, with such weights involved and the high cost of such devices, it is important that the device be mounted correctly on the first attempt: if the device is not correctly mounted on the first try, there is a high risk of damaging the device and causing injury to those installing it.

With the above considerations in mind, there have been various attempts to develop mounting systems that address these concerns. Besides the flat wall mounts, there have been mounts produced that include one or more articulating arms. The articulating type of mount generally allows a flat panel to be placed nearly flat against the wall, or moved straight out away from the wall varying distances (mount dependant) and swing to the left or right. Installers can also recess the flat panel television into a cabinet or fixture (with an articulating mount) flush with the outer wall surface. The articulating mount then allows the TV to come out of the recess and pivot to the left or right, providing different viewing angles.

Flat panel televisions are ever increasing in size, and as they become less expensive, consumers are buying the largest they can afford. Flat panel televisions also conveniently provide twice the screen size of a “tube” unit, resulting in a more enjoyable viewing experience. Customers are trying to fit the largest flat panel television into limited space: such as just above a fire place mantel, or in a corner up against the ceiling. These examples require a specific orientation of the display for the perfect installation effect and viewing angle.

### SUMMARY OF THE INVENTION

Various embodiments of the present invention provide a moveable mounting system for use with a variety of devices, particularly display devices such as flat panel displays. One or more articulating arm may be used in the various configurations of the present invention to provide translational and rotational adjustment of the attached display device in relation to a mounting surface. The display device may be adjustably orientated in relation to the mounting surface, from a retracted position proximate the surface to a fully extended position away from the wall, as well as any intermediate position therebetween. The moveable mounting system is configured to have a low profile such that the rear of the display device may be positioned in close proximity to the mounting surface when the adjustably mounting system is fully retracted, further enhancing the aesthetics of the flat panel display. The articulating arms also permit adjustable rotation of the display device up to about 90 degrees in a clockwise and counterclockwise direction. Thus, when the moveable mounting system is attached to a substantially vertical surface such as a wall, the attached display can be rotated about a substantially vertical first axis up to about 180 degrees. Furthermore, a tilting assembly mechanism can provide adjustment of the attached device with respect to the orientation and the viewing angle about a second axis of rotation substantially normal to the first axis of rotation.

In an embodiment, a moveable mounting system provides a surface plate adapted for attachment to the mounting surface and a plurality of surface pivots that are at least partially nested in the surface plate. The mounting system further includes an arm assembly comprising a plurality of arms. The plurality of arms include a first arm that is rotatably connected to one of the a plurality of surface pivots, a second arm rotatably connected to another of the plurality of surface pivot s, a third rotatably connected the first arm, and a fourth arm rotatably connected to the second arm. The moveable mounting system further includes a device bracket with a central axle that is rotatably connected to the third arm and the fourth arm. Further, at least a portion of the third and fourth arms are nestable with each other when the moveable mounting system is extended. The moveable mounting system is selectively moveable between an extended orientation, where the device bracket is disposed a distance from the surface plate, and a retracted orientation, where the device bracket is disposed proximate the surface plate and where the first and second arms are substantially parallel to the surface plate.

These and other features of the invention, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is an exploded view of a moveable mounting system constructed in accordance with an embodiment of the present invention;

FIG. 2 is a side plan view of the moveable mounting system of FIG. 1 in a partially extended orientation with a flat panel display attached;

FIG. 3 is a top view of the moveable mounting system of FIG. 1 in a partially extended orientation with a flat panel display attached;

FIG. 4 is a perspective of a portion of the of the moveable mounting system of FIG. 1;

FIG. 5 is a side plan view of a portion of the of the moveable mounting system of FIG. 1 with a flat panel display attached;

FIG. 6A is a perspective view of the moveable mounting system of FIG. 1 in an extended orientation with a flat panel display attached, and FIG. 6B is a top view of the moveable mounting system of FIG. 1 in an extended orientation with a flat panel display attached;

FIG. 7 is a front perspective view of a portion of the moveable mounting system of FIG. 1 in a retracted orientation;

FIG. 8 is a rear perspective view of the moveable mounting system of FIG. 1 in a retracted orientation; and

FIG. 9 is a rear perspective view of the moveable mounting system of FIG. 1 in a partially extended orientation with a flat panel display attached.

### DETAILED DESCRIPTION OF VARIOUS EMBODIMENTS

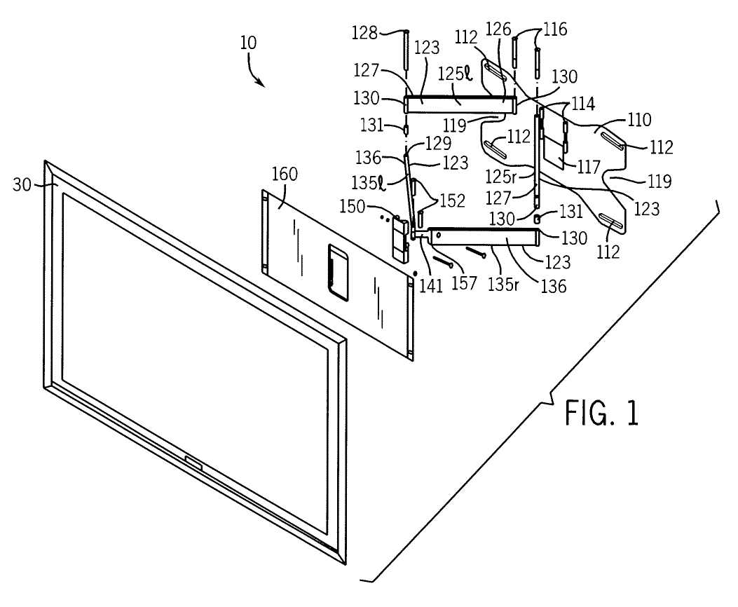

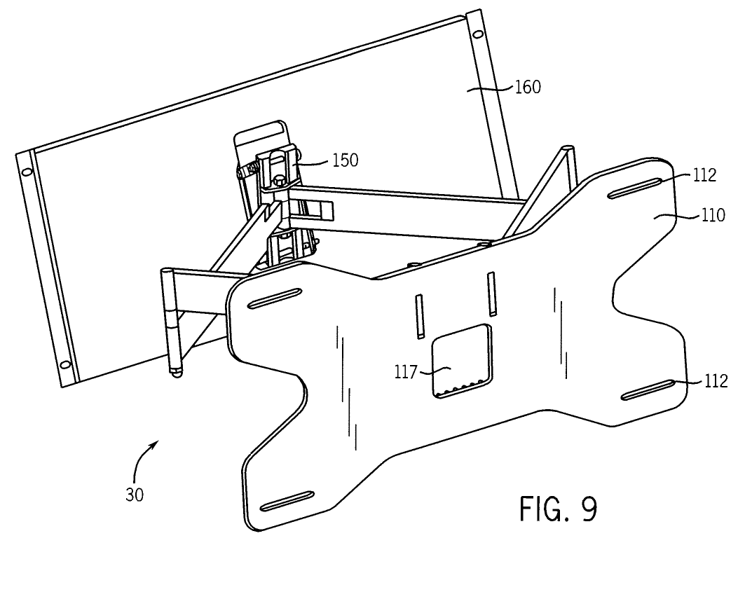

FIGS. 1-9 show a moveable mounting system 10 constructed in accordance with an embodiment of the present invention. The moveable mounting system 10 comprises a surface plate 110, an arm assembly 120 that includes a surface end 121 operatively connected to the surface plate 110 and a device end 122 operatively connected to a device bracket 150, and a device adapter 160 operatively connected to the device bracket 150. The arm assembly 120 comprises one or more arms rotatably attached to one another and may include, as shown, a first arm assembly 21 and a second arm assembly 22. As discussed in detail below, the above described features may be particularly configured to provide a low profile moveable mounting system where the mounted display may be orientated in close proximity to the mounting surface when the moveable mounting system is fully retracted.

In the embodiment depicted in FIGS. 1-9, the surface plate 110 comprises a relatively thin plate that can be affixed to a wall or other desired surface via a plurality of openings 112 for accepting bolts, screws, or other connecting elements. It should be noted that, in various embodiments of the present invention, the plurality of openings 112 are substantially horizontally spaced openings commensurate with standard wall stud spacing. Additionally, in various embodiments of the present invention, each of the plurality of openings 112 is a substantially horizontally elongated slot to allow for variations that can be experienced with the standard wall stud spacing. The plurality of openings 112 may include a surrounding recess configured such that a head of the connecting element does not substantially protrude from the face of the surface plate 110, thereby not increasing the overall thickness or profile of the moveable mounting system 10.

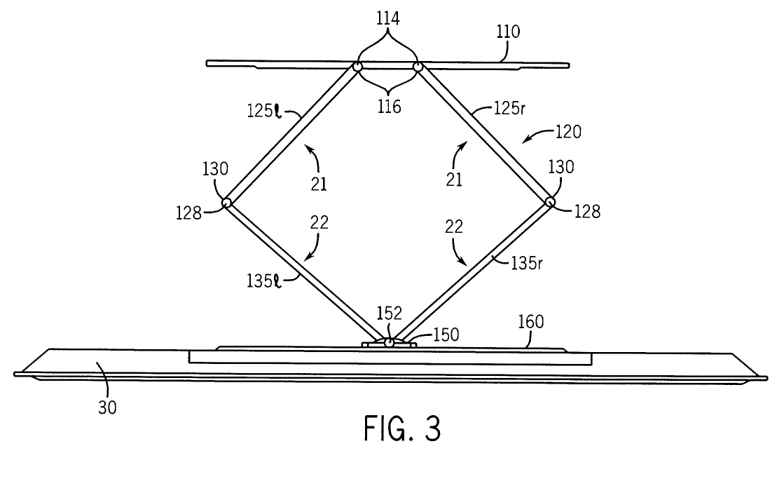

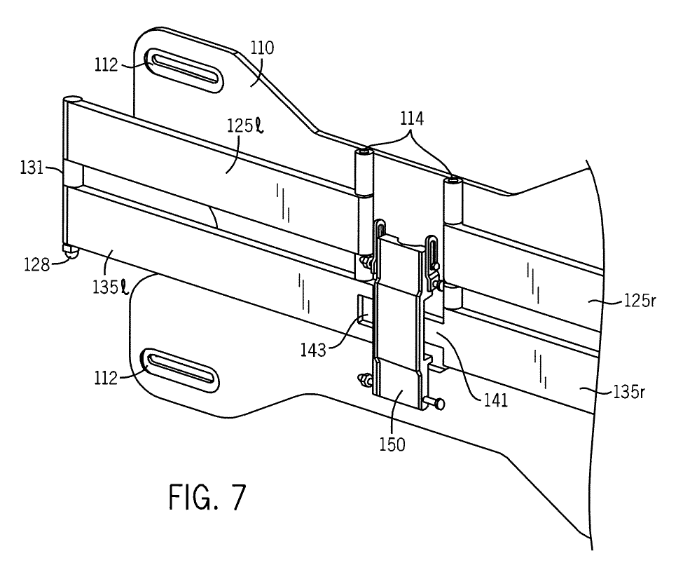

The surface plate 110 further comprises a surface pivot 114 disposed on the face of the surface plate 110. The surface pivot 114 is configured to rotatably connect the surface end 121 of the arm assembly 120 to the surface plate 110. As shown in FIG. 1, the surface pivot 114 may comprise a portion of a hinge and include one or more protrusions adapted to receive, for example, a surface axle 116. The surface axle 116 may be integral to or receivable by the arm assembly 120. As shown in FIG. 3, where the moveable mounting system 10 includes a first arm 125l and a second arm 125r, the surface plate 110 may include two or more surface pivots 114 horizontally or vertically offset from each other. Each of the surface pivots 114 may be configured to rotatably connect to the first arm 125l or the second arm 125r. Alternatively, the surface plate 110 may include a single surface pivot 114 configured to rotatably couple to the first arm 125l and the second arm 125r. In this configuration (not shown), a portion of the first arm 125l and the second arm 125r may be configured to partially nest with each other to permit nearly fully extension of the arm assemblies 120 without interference. In either configuration the surface pivot 114 may be welded, attached by connecting elements, integrally formed or otherwise connected to the surface plate 110. As shown in FIGS. 3 and 7, the surface pivot 114 is integrally formed and partially recessed in the surface plate 110 such that at least a portion of the opening of the surface pivot 114 is disposed below the face of the surface plate 110. Accordingly, the surface pivot 114, when at least partially recessed in the surface plate 110, allows the arm assembly 120 to be folded substantially parallel and in close proximity to the surface plate 110, providing the moveable mounting system 10 with a relatively thin profile when fully retracted.

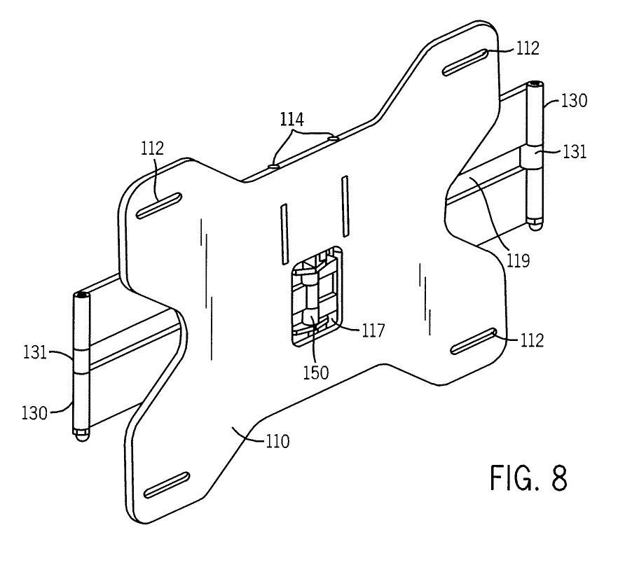

The surface plate 110 may further include one or more apertures or recesses to receive portions of the of the moveable mounting system 10 when in the retracted configuration. For example, a bracket aperture 117 may be included in the surface plate 110 to receive a portion of the device bracket 150 when the moveable mounting system is fully or partially retracted as shown in FIGS. 7 and 8. To further accommodate a portion of the device bracket 150, a portion of the wall or mounting surface underlying the bracket aperture 117 may also be removed, allowing a portion of the device bracket 150 to be received in the void formed in the wall or mounting surface. Additionally, as required, the surface plate 110 may include an arm pivot opening 119 to correspond with the location of a pivot between the arms of the arm assembly 120. Each of these features reduces or eliminates a point of interference among components in the moveable mounting system 10, thereby providing the moveable mounting system 10 with a relatively thin profile when fully retracted.

The arm assembly 120 is rotatably affixed to the surface plate 110 at one or more surfaces pivot 114. The arm assembly 120 may comprise a single arm 123 operatively connecting the surface plate 110 and the device bracket 150 or a plurality of rotatably connected arms 123. In the depicted embodiment, the arm assembly 120 comprises a first arm assembly 21 and a second arm assembly 22. As shown in FIG. 3, the first arm assembly 21 includes a first arm 125l and a second arm 125r rotatably connected to the surface plate 110. Similarly, the second arm assembly 22 includes a third arm 1351 and a fourth arm 135r rotatably attached to the device bracket 150. The first, second, third, and fourth arms 1251, 125r, 135l, and 135r generally comprise elongated members of a relatively thin construction to minimize the thickness of the moveable display mount 10 when fully retracted. It will be appreciated that the arms 123 will be sized to adequately support the anticipated weight of a mounted device in retracted, intermediate, and fully extended orientations.

The first and second arms 125l and 125r each include a first end 126 and a second end 127 distal the first end 126. The third and fourth arms 135l and 135r each include a third end 136 and a fourth end 137 distal the third end 136. A pivot portion 130 is disposed proximate the first end 126, the second end 127, the third end 136, and the fourth end 137. The pivot portions 130 disposed at the first end 126 are configured to rotatably connect the first and second arms 125l and 125r to the surface plate 110. Similarly, the pivot portions 130 disposed at the fourth ends 137 are configured to rotatably connect the third and fourth arms 135l and 135r to the device bracket 150. Also, the pivot portions 130 disposed at the second ends 127 and the pivot portions 130 disposed at the third ends 136 are configured to rotatably couple the first arm 1251 to the third 135l and rotatably couple the second arm 125r and fourth arm 135r. Each of the pivot portions 130 may include a hollow portion for accepting an axle or pin. Alternatively, one or more of the pivot portions 130 may include a post portion that may serve as an axle or a portion thereof and receivable by the corresponding rotatably coupled structure.

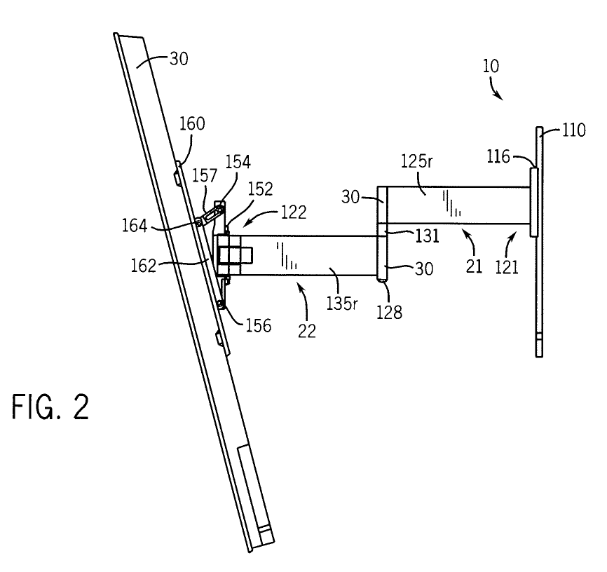

As shown in FIG. 2, the first arm 125l and third arm 135l are rotatably coupled in a vertically stacked configuration such that the first arm 125l is disposed above the third arm 135l. This configuration may be reversed so that the third arm 135l is disposed above the first arm 125l. In either orientation, the second end 127 is orientated with the third end 136 such that the respective pivot portions 130 are substantially axially aligned. The second arm 125r and the fourth arm 135r are similarly coupled. Further, as shown in FIGS. 3 and 8, the pivot portions 130 of the arms 123 are rearwardly offset toward the surface plate 110 and at least partially nestable within the arm pivot opening 119. Accordingly, the first and second arms 125l and 125r and the third and fourth arms 135l and 135r may fold substantially flat against the surface plate 110 when the arm assembly 120 is fully retracted as shown in FIGS. 7 and 8 and the pivot portions 130 of the arm assembly 120 may be at least partially nested within the surface plate 110, providing a low profile. The profile of the moveable mounting system 10 may further be reduced by including one or more recesses (not shown) in the surface plate 110 adapted to partially receive the arms 123 when the arm assembly 120 is fully retracted.

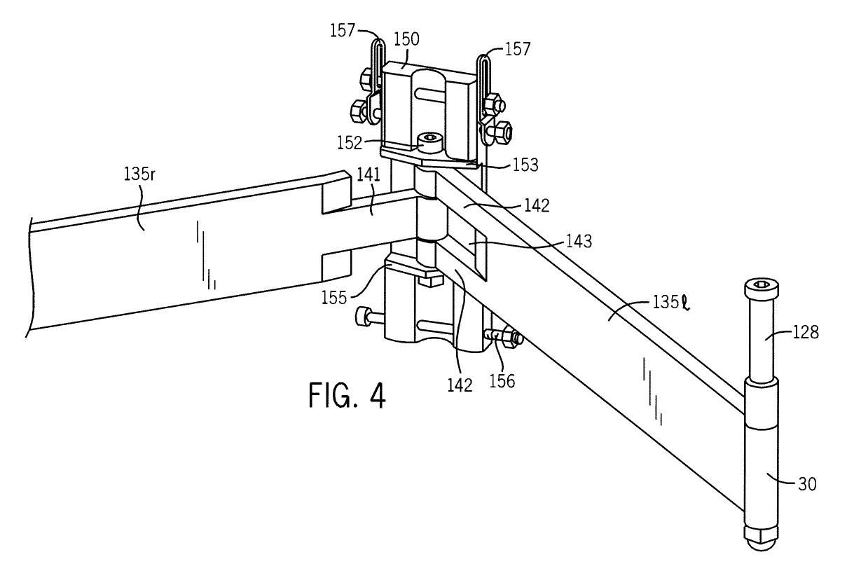

The first arm 125l is rotatably coupled with the third arm 135l, for example, by an arm axle 128 received by the respective pivot portions 130. A bushing 131 may be interposed between the second end 127 and the third end 136 to vertically offset the first arm 125l and the third arm 135l. The bushing 131 may also be adapted to provide a desired frictional bearing surface between the first arm 125l and the third arm 135l during rotation of the respective arms. The arm axle 128 may include an adjustment feature that may be selectively adjusted, for example, by tightening or loosening, to increase or decrease the friction between the first arm 125l and the third arm 135l. As shown in FIG. 4, the adjustable arm axle 128 may, for example, comprise a connecting shaft and a fastening element. The adjustment feature may also be included at the interface between the arm assembly 120 and the surface plate 110 and the arm assembly 120 and the device bracket 150. The relative ease of horizontal adjustment and rotation of the of the moveable display mount 10 may thus be controlled through adjustment of one or more arm axles 128.

As described above, at a surface end 121 of the arm assembly 120, the first arm 125l is rotatably coupled via the pivot portion 130 disposed at the first end 126 to the surface pivot 114. At a device end 122 of the arm assembly 120 distal from the surface end 121, the third arm 135l is rotatably coupled to the device bracket 150. In embodiments that include additional arms, the second and third arms 125r and 135r are similarly rotatably coupled to the surface plate 110 and the device bracket 150 at their respective ends. As described with regard to the surface plate 110, the third arm 135l and the fourth arm 135r may be separately coupled to the device bracket 150. Alternatively, as depicted in FIGS. 3 and 4, the third arm 135l and the fourth arm 135r may be rotatably coupled to the device bracket 150 at a single axis of rotation. In this configuration, the third arm 135l and the fourth arm 135r are rotatably coupled to a central axle 152 operatively connected to the device bracket 150.

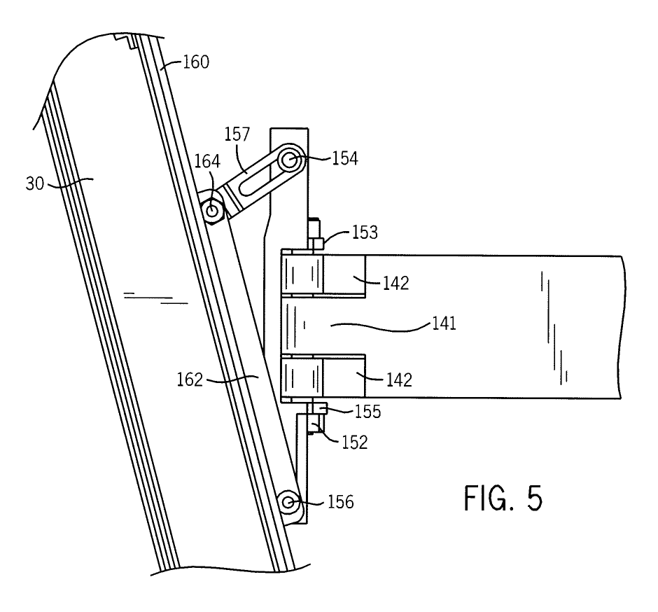

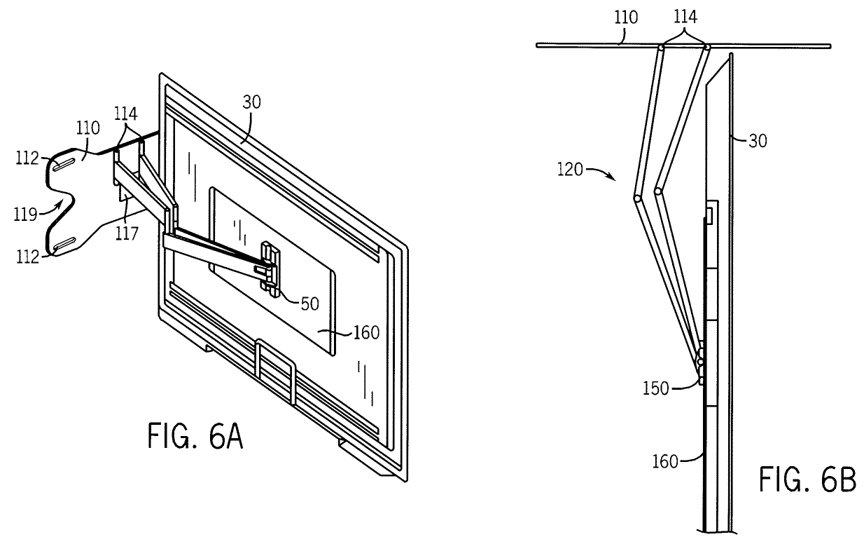

As shown in FIGS. 4 and 5, the device bracket 150 include the central axle 152 rotatably fixed in a top plate 153 and a bottom plate 155 forming a substantially vertical axis of rotation. The third and fourth arms 135l and 135r may freely rotate about this axis. Further, a device operatively connected to the device bracket 150 may be pivoted about the axis of rotation defined by the central axle 152 as shown in FIGS. 6A and 6B. As depicted, the third and fourth arms 135l and 135r may be configured to partially nest proximate the central axle 152. When the moveable mounting system 10 approaches full extension, a portion of the third and fourth arms 135l and 135r nests with each other, thereby permitting further extension of the arm assembly 120. A nestable configuration of the arm assembly 120 may be achieved, for example, by providing the fourth arm 135r with a central tab 141 near the fourth end 137. The pivot portion 130 at the fourth end 137 may accordingly be disposed on the central tab 141 and the rotatably coupled to the central axle 152. The third arm 135l may include a partial “U” configuration with upper and lower peripheral tabs 142 and a corresponding central recess 143. The central recess 143 is configured to substantially align and partially receive the central tab 141, allowing for the arm assembly 120 to be further extended when the moveable mounting system 10 is fully extended. Other variations may also be constructed permitting similar nesting and extension of the arm assembly 120. As shown in FIGS. 6A and 6B, the nested arm arrangement permits, for example, an attached display device to rotate about the central axle 152 about 90 degrees in either direction from a plane substantially parallel to the mounting surface.

As shown in FIG. 3, for example, the device bracket 150 is operatively connected to the device adapter 160. The device bracket 150 may include a tilt capability that provides for rotation of the attached device about a substantially horizontal axis of rotation. As shown in FIG. 5, the device bracket 150 may include a top axle 154 disposed near the upper portion of the device bracket 150 and a bottom axle 156 disposed near the bottom of the device bracket 150. One or more tilt links 157 are slidingly coupled to the top axle 154 and rotatably coupled to the device adapter 160. The bottom axle 156 rotatably couples the device bracket 150 and device adapter 160. The attached device is tilted downward by pulling an upper portion the attached device away from the mount surface, thereby sliding the pivot link 157 in relation to the top axle 154 and rotating the attached device about an axis of rotation defined by the bottom axle 156. As described above, the ease of rotation of the attached device may be adjusted by altering the friction at the top and or bottom axles 154 and 156. Further, the device adapter 160 may be configured for attachment to the device such that device is at least partially self balancing about the axis of rotation defined by the bottom axle 156.

Where the first and second arms 125l and 125r are horizontally separated at the surface plate 110 and the third and fourth arms 135l and 135r are rotatably coupled to each other at the device bracket 150, the length of the third and fourth arms 135l and 135r may be longer than the length of the first and second arms 125l and 125r to compensate for the horizontal separation of first and second arms 125l and 125r on the surface plate 110. Accordingly, the first, second, third, and fourth arms 125l and 125r and 135l and 135r are sized to permit the arm assembly 120 to fold substantially flat proximate the surface plate 110 when the moveable mounting system 10 is fully retracted.

The device adapter 160 comprises a relatively thin plate and may include one or more flanges 162 extending outwardly. The device adapter 160 may include a plurality of openings to receive connecting elements to secure a device to the moveable mounting system. In a particular embodiment, the plurality of openings may substantially correspond to a standard hole pattern for a device such as a flat panel display. In another embodiment, the device adapter 160 may include a plurality of protrusions such as screws, for mating with threaded inserts disposed on the device, allowing the device adapter 160 to be secured to the device. The one or more flanges as shown in FIG. 5, include openings to receive a tilt axle 164 and the bottom axle 156. The tilt axle 164 is rotatably coupled to the tilt link 157. Additionally, the device adapter 160 and a flat screen display device 30 can then be attached to the device bracket 150 as described above. Furthermore, the flat screen display device 30 can be oriented in either a portrait or landscape mode depending on how the device adapter 160 is attached to the device bracket 150, or by adjusting the orientation of the flat screen display device relative to the device adapter 160.

In an embodiment of the present invention, the moveable mounting system 10 is configured to mount the flat panel display 30. However, other types of devices could also be mounted on the moveable mounting system 10. The weight of the flat panel display 30 is distributed by the arm assembly 120. The flat panel display 30 may be extended away from the mounting surface by grasping the display and pulling outward away from the mounting surface, thereby extending the arm assembly 120. Likewise, pushing the flat panel display 30 toward the mounting surface retracts the arm assembly 120 and the display may be positioned in close proximity to the mounting surface. The flat panel display 30 may be orientated in an intermediate orientation and rotated about a vertical axis where the moveable mounting system is mounted to a substantially vertical wall. In a particular embodiment, the rear of the flat panel display 30 may be positioned as close as about 0.75 inches from the surface when fully retracted. The flat panel display 30 may be rotated in a substantially horizontal plane about the surface pivot 114 when extended from a substantially vertical mounting surface and rotated about the central axle 152 up to about 180 degrees when fully extended. Further, the flat panel display 30 may be tilted about an axis substantially normal to the central axle defined by the bottom axle 156. The above adjustments can accommodate a variety of viewing locations and viewing angles.

The foregoing description of embodiments of the present invention have been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments and with various modifications as are suited to the particular use contemplated. The features of the embodiments described herein may be combined in all possible combinations of methods, apparatus, modules and systems.

What is claimed is:

1. A moveable mounting system for attaching a device to a surface, comprising:
a surface plate adapted for attachment to the surface;
one or more surface pivots operatively connected to the surface plate;
an arm assembly comprising a plurality of arms including:
a first arm rotatably connected at its first end to one of the one or more surface pivots;
a second arm rotatably connected at its first end to one of the one or more surface pivots;
a third arm rotatably connected to a second end of the first arm;
a fourth arm rotatably connected to a second end of the second arm; and
a device bracket rotatably connected at a central axle to the third arm and the fourth arm,
wherein a portion of the third arm and a portion of the fourth arm proximate the central axle are partially nestable with each other, and wherein the moveable mounting system is selectively moveable between an extended orientation, where the device bracket is disposed a distance from the surface plate, and a retracted orientation, where the device bracket is disposed proximate the surface plate and where the first and second arms are substantially parallel to the surface plate.

2. The moveable mounting system of claim 1, wherein the surface plate includes a device bracket opening configured to partially receive at least a portion of the device bracket, and wherein the device bracket is partially nestable within the surface plate when in the retracted orientation.

3. The moveable mounting system of claim 2, wherein the one or more surface pivots are at least partially recessed within the surface plate.

4. The moveable mounting system of claim 3, wherein at least a portion of the device bracket is receivable within a void in the surface underlying the device bracket opening when the moveably mounting system is in the retracted orientation.

5. The moveable mounting system of claim 1, wherein the first and second ends of the first and second arms are characterized by a pivot portion adapted to receive an arm axle.

6. The moveable mounting system of claim 5, wherein the arm axle is selectively adjustable to modify rotational friction between one the plurality of arms in relation to another of the plurality of arms.

7. The moveable mounting system of claim 1, wherein the surface plate includes a pivot opening configured to partially receive at least a portion of the arm assembly when the adjustable mounting system is in the retracted orientation.

8. The moveable mounting system of claim 1, wherein the device may be rotated substantially 180 degrees about the central axle when the moveable mounting system is in at least a partially extended orientation.

9. The moveable mounting system of claim 1, further comprising a device adapter rotatably coupled to the device bracket, wherein the device adapter is adapted for mounting a flat panel display device, and wherein the flat panel display device is tillable about a substantially horizontal axis of rotation substantially parallel to the surface.

10. The moveable mounting system of claim 9, wherein the moveable mounting system is orientated in the retracted orientation and the flat panel display device is substantially parallel to the surface, and wherein a rear surface of the flat panel display device is disposed a maximum of about 0.75 inches from the surface.

11. The moveable mounting system of claim 1, wherein the first arm is vertically spaced apart from the third arm, and wherein the second arm is vertically spaced apart from the fourth arm.

12. A moveable mounting system configured to attach a device to a mounting surface, comprising:
a surface plate adapted for attachment to the mounting surface and including an opening;
a plurality of surface pivots at least partially recessed in the surface plate;
a first arm assembly including:
a first plurality of arms, each of the first plurality of arms including:
a first pivot portion rotatably connected to one of the plurality of surface pivots, and
a second pivot portion;
a second arm assembly including:
a second plurality of arms, each of the second plurality of arms rotatably connected to one of the first plurality of arms at the second pivot portion, the second plurality of arms at least partially nestable with each other; and
a device bracket rotatably connected to the second plurality of arms,
wherein the moveable mounting system is selectively moveable between an extended orientation, where the device bracket is horizontally disposed a distance from the surface plate, and a retracted orientation, where the device bracket is at least partially nested within the opening.

13. The moveable mounting system of claim 12, wherein the first pair of arms comprises a left first arm and a right first arm, and wherein the second pair of arms comprises a left second arm and a right second arm.

14. The moveable mounting system of claim 12, further comprising a central axle operatively connected to the device bracket, wherein the second plurality of arms are rotatably connected to the central axle.

15. The moveable mounting system of claim 14, wherein the device is rotatable substantially 180 degrees about an axis of rotation defined by the central axle.

16. The moveable mounting system of claim 12, wherein the first plurality of arms is vertically separated from the second plurality of arms.

17. The moveable mounting system of claim 12, further including a device adapter rotatably coupled to the device bracket, and wherein the device adapter is adapted for attachment to a flat panel display device.

18. The moveable mounting system of claim 12, wherein the first plurality of arms and the second plurality of arms are substantially parallel and proximate the surface plate when the moveable mounting system is in the retracted orientation.

19. The moveable mounting system of claim 12, wherein at least a portion of the first pivot portion and the second pivot portion are partially nestable in the surface plate.

20. A moveable mounting system configured to attach a display device to a mounting surface, comprising:
a surface plate adapted for attachment to the mounting surface and having an opening;
an arm assembly including a first arm and a second arm, the first arm rotatably attached to the surface plate and a medial pivot, the medial pivot rotatably connecting the first arm and the second arm;
a device bracket rotatably connected to the second arm distal the medial pivot; and
a display device operatively connected to the device bracket,
wherein the moveable mounting system is selectively moveable between an extended orientation, where the device bracket is horizontally disposed a distance from the surface plate, and a retracted orientation, where the device bracket is at least partially nested within the opening.
